(19) United States
(12) Patent Application Publication
(10) Pub. No.: US 2009/0128177 A1
(43) Pub. Date: May 21, 2009

(54) ATTACHMENT FOR SOCKET AND SEMICONDUCTOR DEVICE-TESTING UNIT HAVING THE SAME

(76) Inventor: Toshio Ohta, Tokyo (JP)

Correspondence Address: 3M INNOVATIVE PROPERTIES COMPANY, PO BOX 33427, ST. PAUL, MN, 55133-3427, US

(21) Appl. No.: 12/300,729

(22) PCT Filed: Jun. 19, 2007
(86) PCT No.: PCT/US2007/701512

§ 371 Date: Nov. 13, 2008

(30) Foreign Application Priority Data
Jul. 3, 2006 (JP) 2005-183342

(51) Int. Cl. G01R 31/02

(52) U.S. Cl. 324/755

(57) ABSTRACT

To provide an attachment for a socket which can cope with automatic testing of the IC devices, and which can enhance the radiation of heat from the IC devices despite of its reduced size, as well as to provide a semiconductor device-testing unit having the same. An attachment 15 for a socket used together with an IC socket 1 for connecting a BGA chip 10 to a testing circuit, to test the BGA chip 10 for its performance, wherein provision is made of a pair of heat sinks 19 of a half-split structure that come in contact with the surface of the BGA chip 10 to remove the heat generated by the BGA chip 10.

### TECHNICAL FIELD

The present invention is concerned with an attachment for a socket, mounted on a socket for connecting semiconductor devices such as BGA (ball grid array) chips to a testing circuit, and with a semiconductor device-testing unit having the same.

### BACKGROUND

Some sockets, used for connecting a semiconductor device such as a BGA chip (hereinafter called an IC device) manufactured by a semiconductor process to a testing circuit for testing the performance, have been provided with a heat sink for removing heat generated by the IC device, during testing, to the exterior. IC sockets equipped with a heat sink are known as disclosed in Japanese Patent Nos. JP-A-2003-7942 and JP-A-2003-7942.

The IC socket disclosed in the Japanese Patent No. JP-A-2003-7942 is known as a separation type in which the heat sink is detachably attached to the socket body. The IC socket disclosed in the Japanese Patent JP-A-2003-59602 is known as an integrated type in which the heat sink is mounted integrally on the socket body.

In the IC socket of the separation type, in general, the heat sink is detachably mounted on a socket body that is fixed on a board of a testing circuit. The IC socket of the Japanese Patent No. JP-A-2003-7942 includes a socket body fixed on a board and having contacts that are electrically contacted to a plurality of contacts exposed on the back surface side of an IC device, a top cover resiliently supported by the socket body, and an attachment having a heat sink of the integrated type. The IC device which is an object to be tested is detachably mounted on the top cover. The attachment is detachably fixed to a fixing plate arranged surrounding the socket body. With the attachment being fixed to the fixing plate, the heat sink is arranged on the IC device.

The IC socket of the integrated type, on the other hand, does not permit the heat sink to be removed from the socket body. In the IC socket of the Japanese Patent JP-A-2003-59602, a pair of heat sinks of a half-split structure is coupled to the top cover that holds the IC device so as to be opened and closed via hinges. The pair of heat sinks open while being linked to the motion of the top cover and permit the IC device to be exchanged.

### SUMMARY

In the IC socket of the separation type, the attachment having heat sinks must be removed from the fixing plate every time the IC device is to be exchanged, requiring cumbersome work. Therefore, this structure is not suited for automatically testing may IC devices for their performance.

Further, the IC socket of the integrated type involves a problem in that the structure of the IC socket becomes complex resulting in an increase in the size. When it is required to mount an increased number of IC sockets in a limited space, it is not possible to increase the number of the IC sockets, and the performance testing is not efficiently conducted. From the structural limitation, further, it is not possible to increase the size of the heat sinks, and the heat-radiating performance is poor.

The IC socket having heat sinks integrated together can also be used for testing IC devices that generate heat in small amounts. However, presence of the heat sinks causes the IC socket to become bulky bringing about a problem in that only a decreased number of the devices (decreased number of the test boards) can be introduced in a stacked state into the oven for accelerated testing as compared to when IC sockets without heat sinks are used. Therefore, the socket having heat sinks is used for testing only those IC devices that generate heat in large amounts, and is used in only limited ranges (or is not effectively utilized).

It is, therefore, an object of at least one aspect of the present invention to provide an attachment for a socket which can cope with automatic testing of the performance of the IC devices, and which can enhance the radiation of heat from the IC devices despite of its reduced size, as well as to provide a semiconductor device-testing unit having the same.

In order to solve the above problems, an attachment for a socket described in claim 1 is an attachment for a socket used together with a socket for connecting a semiconductor device to a testing circuit, to test the semiconductor device for its performance, wherein provision is made of a pair of heat-radiating portions of a half-split structure that can be opened and closed and are in contact with the surface of the semiconductor device to remove the heat generated by the semiconductor device to the exterior.

According to the invention described in claim 1 of this application, the socket is separated away from the heat-radiating portions avoiding an increase in the size of the socket that results from the complexity in the structure. The heat-radiating portions are not formed in a compact size and, hence, maintain relatively large contact areas with the IC device, making it possible to enhance the heat radiation. Further, the pair of heat-radiating portions are of a half-split structure and can be opened and closed, enabling the IC device to be exchanged in a state where the pair of heat-radiating portions are opened and lending themselves well to automatic testing of the IC devices.

The invention of claim 2 is an attachment for a socket according to claim 1, including a base frame; a top frame supported on the base frame resiliently floating thereon; and a pair of arms of which the ends on one side are fixed ends pivotally coupled to a pair of opposing sides of the top frame, and of which the ends on the other side are free ends, the pair of arms pivotally moving so as to be opened and closed relative to each other while being linked to the lifting motion of the top frame with the pivot shafts as fulcrums; wherein the pair of heat-radiating portions are resiliently provided on the other end side of the pair of arms and come into contact with the surface of the semiconductor device when the pair of arms are closed and separate away from the surface of the semiconductor device when the pair of arms are opened.

According to the invention described in claim 2, the pair of arms open and close while being linked to the up-and-down motion of the top frame. By being brought into synchronism with the opening/closing operation of the existing IC socket, therefore, the IC device can be exchanged by a single motion in the up-and-down direction. By using on existing machine that moves in the up-and-down direction, therefore, the IC devices can be automatically tested for their performance. Therefore, the IC devices can be automatically tested without increasing the facility cost.

The invention of claim 3 is an attachment for a socket according to claim 2, wherein a pair of coupling portions supported by the pivot shafts are provided facing each other on one end side of the arms, and an opposing gap between the pair of coupling portions is equal to, or narrower than, the width of the heat-radiating portions.

According to the invention described in claim 3, an opposing gap between the pair of coupling portions is equal to, or narrower than, the width of the heat-radiating portions, making it possible to decrease the size of the attachment on the side at right angles to the opposing direction in which the arms are provided. Therefore, the IC sockets can be arranged in a large number on the narrow side of the attachment, and efficiency of testing the IC devices can be enhanced.

The invention of claim 4 is an attachment for a socket according to any one of claims 1 to 3, wherein the heat-radiating portions are so provided as to swing in a direction at right angles to the direction of pivot shafts of the arms.

According to the invention described in claim 4, the heat-radiating portions can swing in a direction at right angles to the direction of the pivot shafts of the arms. When the surface of the semiconductor device has varying heights, therefore, the posture can meet the surface conditions. Therefore, a favorable contact is maintained between the semiconductor device and the heat-radiating portions, and the heat radiation can be enhanced.

The invention of claim 5 is an attachment for a socket according to any one of claims 2 to 4, wherein the base frame is provided with upwardly directed guide pieces which do not protrude beyond the upper surface of the top frame when the top frame is pushed down, the guide pieces being slide-engaged with guide grooves of the top frame to guide the motion of the top frame in the up-and-down direction.

According to the invention described in claim 5, guide pieces of the base frame and guide grooves in the top frame constitute a guide mechanism for guiding the motion of the top frame in the up-and-down direction. As compared to when the guide mechanism is constituted by providing separate members such as bearings, therefore, the structure can be simplified and requires a small number of parts, and the size can be decreased as a result of saving space. Further, as the ends of the guide pieces do not protrude beyond the upper surface of the top frame, interference is avoided between the guide pieces and the arms or the heat-radiating portions.

The invention of claim 6 is an attachment for a socket according to any one of claims 1 to 5, which is detachably mounted on a circuit board which forms the testing circuit.

According to the invention described in claim 6, an attachment for a socket is detachably mounted on a board of a testing circuit. When a semiconductor device that produces a small amount of heat is to be tested, therefore, the attachment for a socket may be removed, and the testing may be conducted by using the socket only. This makes it possible to flexibly test semiconductor devices in a variety of ways.

The invention of claim 7 is a semiconductor device-testing unit for connecting a semiconductor device to a testing circuit, to test the semiconductor device for its performance, including a socket having many contacts which are brought at the ends on one side thereof into electric contact with conducting portions exposed on the back surface of the semiconductor device and are brought at the ends on the other side into electric contact with the testing circuit to thereby trunk-connect the semiconductor device to the testing circuit in a state where the semiconductor device is being held; and the attachment for a socket, of any one of claims 1 to 6, that is used together with the socket.

According to the invention described in claim 7, a variety of semiconductor devices can be tested for performance owing to a synergistic effect of the socket and the attachment for socket, in addition to the effect, of claims 1 to 6, to expand the range of applications.

### BRIEF DESCRIPTION OF THE DRAWINGS

FIG. 1 is a perspective view illustrating an embodiment of an attachment for a socket according to the present invention together with an IC socket;

FIG. 2 is a view illustrating, on an enlarged scale, the attachment for a socket shown in FIG. 1;

FIG. 3 is a disassembled perspective view of the attachment for a socket; and

FIG. 4 is a perspective view illustrating a state where the heat sinks in the attachment for socket are opened.

### DETAILED DESCRIPTION

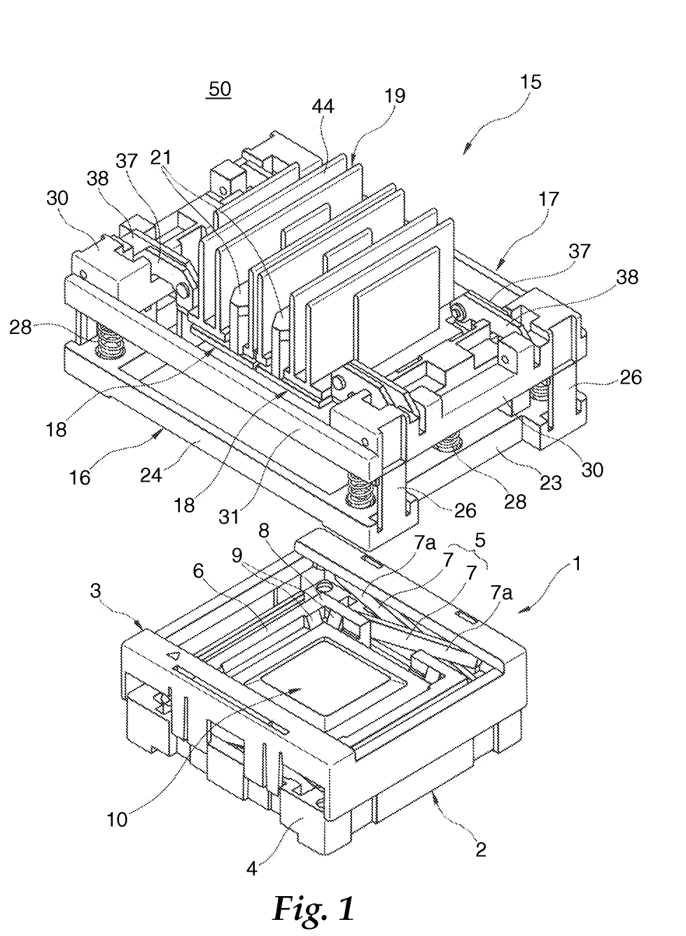

A concrete embodiment of the present invention will now be described in detail with reference to the drawings. In the drawings, common portions are denoted by the same reference numerals but are not described repeatedly. FIG. 1 is a view illustrating an attachment 15 for socket of the embodiment used for an IC socket 1. The attachment 15 for socket of the embodiment is used together with the IC socket 1 without a heat sink, and is set on the outer side of the IC socket 1. A semiconductor device-testing unit 50 is constituted by the IC socket 1 and the attachment 15 for a socket. In a state where the attachment 15 for a socket is set, an opening of the IC socket 1 is covered with heat sinks 19 leaving gaps through which the air flows to some extent, and the back surfaces of the heat sinks 19 come in contact with the surface of an IC device 10. As the IC device 10 that is to be set to the IC socket 1, there can be used a BGA chip having solder balls on the back surface thereof.

The IC socket 1 that is shown is the one that is generally used, and includes an alignment plate (not shown) that is fixed to the board of a testing circuit that is not shown, a socket body 2 fixed to the plate, and a top cover 3 resiliently supported by the socket body 2. The alignment plate is obtained by injection-molding an insulating material, and has a region forming many through holes. The through holes are for aligning the leg portions formed at the ends on one side of many contacts (not shown) held by the socket body 2, and are arranged like a lattice in two directions meeting at right angles with each other.

The socket body 2 includes a base 4 having many contact press-inserting portions, a nest assembly (not shown) provided on the socket body 2, a lever assembly 5 also provided on the socket body 2, and a guide frame 6. The base 4 is made of an insulating material and is formed in a rectangular shape corresponding to the alignment plate. A nearly flat base wall portion forms through holes that serve as press-inserting portions at positions corresponding to the many through holes in the alignment plate. Nearly intermediate portions of the contacts in the lengthwise direction thereof are press-inserted in the through holes formed in the base wall portion and are fixed thereto. The contacts are thus held by the base 4.

The contacts, that are not shown, have electrically contacting portions at both ends thereof, the ends on one side serving as leg portions that connect to the testing circuit and the other end side serving as a pair of contact pieces that connect to a solder ball exposed on the back surface of the BGA chip 10. The testing circuit and the IC device are electrically connected to each other through the contacts.

As described in detail in U.S. Pat. No. 5,498,970, the nest assembly is constituted by many pairs of blocks. The blocks are constituted by using an insulating material. Each pair of blocks slide relative to each other, and a pair of contact pieces formed on the end side of contacts are held between each pair of blocks. As each pair of blocks slide relative to each other, a gap between the pair of contact pieces is reduced or increased. When the gap of the pair of contact pieces is narrowed, a solder ball on the BGA chip 10 located at a predetermined position is held. Thus, the contact and the BGA chip 10 are electrically connected to each other.

The lever assembly 5 has two frames 7 made of, for example, a relatively tough metal material. Each frame 7 is constituted by a proximal transverse member and a distal transverse member facing each other, and by a pair of side members 7a facing each other. The frames 7 are coupled in a crossing manner so as to rotate at the intermediate portions of the side members 7a based on a combination of a pin and a hole. Either one of the proximal transverse member or the distal transverse member of the frame 7 comes into contact with the back surface of the top cover 3, and the other one comes in to contact with an end of the block of the nest assembly. When the top cover 3 resiliently supported on the socket body 2 is pushed down, the frames 7 contract in a direction in which they overlap one another. The blocks of the pairs slide relative to each other, and a pair of contact pieces of contacts are opened. At the same time, when the pushing force is removed, the top cover 3 resiliently returns back to the initial position due to a resilient force such as of a spring (not shown) provided between the socket body 2 and the top cover 3, whereby a pair of contact pieces close to maintain a state of contact with the solder ball. The top cover 3 moves up and down being interlocked to the BGA chip 10 that is set on the nest assembly.

The guide frame 6 is for guiding the BGA chip 10 to a proper position of the nest assembly and has a rectangular opening similar to the outer shape of the BGA chip 10. At corner portions 8 of the rectangular opening, guide surfaces 9 are formed inclining inwards from the upper side toward the lower side.

The top cover 3 has, at the central portion thereof, a rectangular opening of a size that does not cause interference when the BGA chip 10 is set, and is resiliently supported by the socket body 2 via a resilient member. The top cover 3 is mounted in a state of being urged upward by the resilient force of the resilient members. An uppermost position where the top cover 3 reaches to is a normal position of the top cover 3 and at which the BGA chip 10 is electrically connected to the IC socket 1. Conversely, a lowermost position where the top cover 2 reaches to is a position for removing the BGA chip 10.

According to the above IC socket 1, the BGA chip 10 is set in a state where the top cover 3 is pushed down, the top cover 3 returns to the initial state when the force is released, and solder balls of the BGA chips 10 are held by pairs of contact pieces of contacts. Thus, the BGA chip 10 is electrically connected to the testing circuit via the contacts.

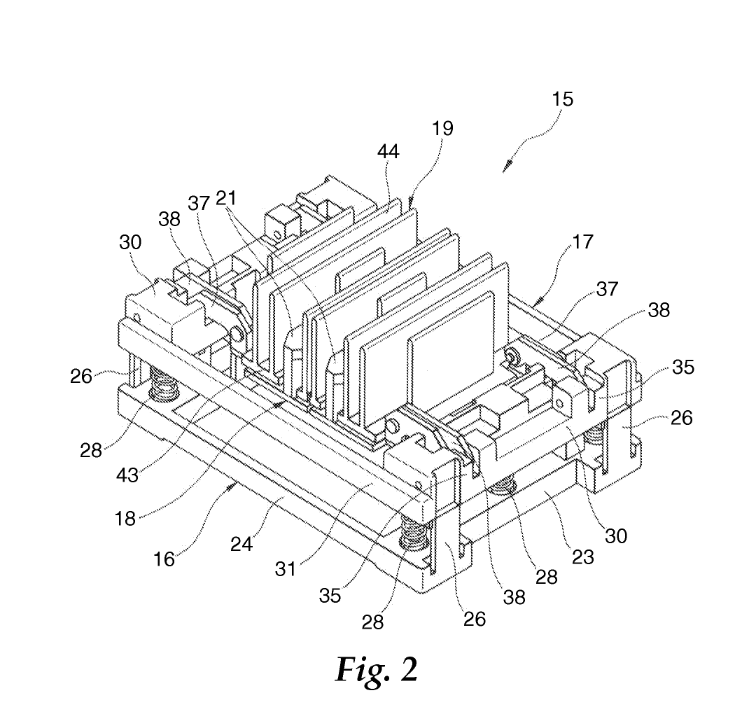

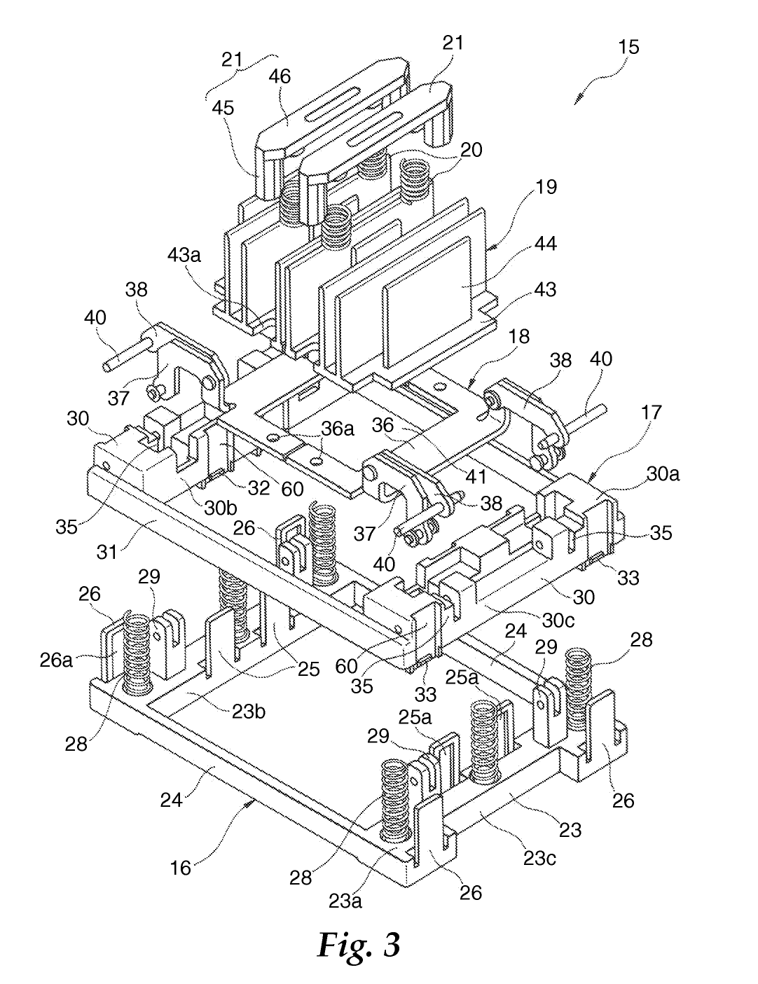

Next, an embodiment of the attachment is for a socket will be described with reference to FIGS. 1 to 3. The attachment 15 for a socket (hereinafter referred to as an “attachment”) of the embodiment is detachably mounted on the board of the testing circuit surrounding the IC socket 1, and includes a base frame 16 mounted on the board, a top frame 17 resiliently supported on the base frame 16 so as to move up and down, a pair of arms 18 provided on the top frame 17 so as to be opened and closed, heat sinks (heat-radiating portions) 19 supported on the arms 18, and holder members 21 for holding the heat sinks 19, so they will not be disengaged, via coil springs 20 interposed relative to the heat sinks 19.

The base frame 16 is obtained by injection-molding a highly heat resistant synthetic resin such as PES (polyethersulfone) resin and has, at the central portion thereof, an opening of a shape similar to the outer shape of the IC socket 1. This opening is nearly of a square shape, and has an IC socket 1 arranged in the opening. The frame is a rectangular shape includes a pair of longitudinal members 23 which are pieces facing each other, and a pair of transverse members 24 which are also pieces facing each other. A pair of inner pieces (guide pieces) 25 are provided in an erect manner on the inner surfaces 23b of the pair of longitudinal members 23, the inner pieces (guide pieces) 25 having, in the outer surfaces thereof, engaging grooves 25a that engage with engaging pawls 32 formed in guide grooves 60 in the inner surfaces 30b of the transverse members 30 of the top frame 17. The length of the engaging grooves 25a corresponds to a length over which the engaging pawls 32 move together with the top frame 17 in the up-and-down direction. The engaging pawls 32 come into contact with the upper edges of the engaging grooves 25a so as to be engaged, whereby the top frame 17 is prevented from moving and remains at the uppermost position.

The inner pieces 25 come into slide-engagement with the guide grooves 60 in the top frame 17. Therefore, the inner pieces 25 are guided by the guide grooves 60, and the top frame 17 moves up and down perpendicularly to the base frame 16.

When the top frame 17 is at the position where it is most pushed down, the inner pieces 25 have such a height that the upper ends thereof do not protrude beyond the upper surfaces of the longitudinal members 30 of the top frame 17. Therefore, when the top frame 17 is pushed down to open the heat sinks 17, there is no possibility of interference between the inner pieces 25 and the heat sinks 19 or the arms 18. This further avoids any limitation on designing the heat sinks 19.

A pair of outer pieces (guide pieces) 26 are vertically provided on the outer surfaces 23c of the longitudinal members 23, the outer pieces (guide pieces) 26 having, in the inner surfaces thereof, engaging grooves 26a that engage with engaging pawls 33 formed in the inner surfaces 30c of the transverse members 30 of the top frame 17. The outer pieces 26 are positioned on the outer sides in the direction of width obliquely to the inner surfaces 25. The length of the engaging grooves 26a corresponds to the length over which the engaging pawls 33 move together with the top frame 17 in the up-and-down direction like that of the inner pieces 25 mentioned above. Due to the pair of inner pieces 25 and the pair of outer pieces 26, the top frame 17 reliably engages with the base frame 16.

The outer pieces 26 come in slide-engagement with the guide grooves 61 in the top frame 17. Therefore, the outer pieces 25 are guided by the guide grooves 61, and the top frame 17 moves up and down perpendicularly to the base frame 16. The outer pieces 26 have such a height that the upper ends thereof do not protrude beyond the upper surfaces of the longitudinal members 30 of the top frame 17 as in the case of the inner pieces 25. When the heat sinks 17 are opened, there is no possibility of interference between the outer pieces 26 and the heat sinks 19 or the arms 18.

As described above, the attachment 15 is provided with a guide mechanism which is constituted by inner pieces 25 and outer pieces 26 protruding on the base frame 16 and guide grooves 60, 61 formed in the top frame 17. Compared to when there is provided a guide mechanism such as bearings as separate members, therefore, the number of parts can be decreased, the structure can be simplified, space can be saved, and the attachment 15 can be provided in a small size.

Three compression coil springs 28 are vertically provided on the upper surface 23a of each of the pair of longitudinal members 23. One end of each compression coil spring 28 is buried in the upper surface 23a of the longitudinal member, and the other end thereof come into contact with the back surface of the longitudinal member 30 of the top frame 17. Thus, the top frame 17 is resiliently supported by a total of six coil springs 28 to maintain a good balance.

On both sides of the upper surfaces 23a of the longitudinal members 23, there are protruded arm support portions 29 for pivotally supporting the ends of coupling portions 37 of the pair of arms 18. That is, both ends of pins 39 provided at the ends of the coupling portions 37 are inserted in the through holes 29a of the arm support portions 29, so that the pair of arms 18 are pivotally supported by the arm support portions 29.

In a state of being resiliently supported by the coil springs 28 as described above, the top frame 17 is mounted on the base frame 16 with the engaging pawls 32 and 33 formed on the inner surfaces 30b and on the outer surfaces 30c of the longitudinal members 30 being engaged with the inner pieces 25 and outer pieces 26 of the base frame 16. Further, hinge support portions 35 are provided on both sides of the pair of longitudinal members 30 to pivotally support, via pins 40, the proximal ends of hinge portions 38 integrally fixed to the inner surfaces of coupling portions 37 of the pair of arms 18.

The pair of transverse members 31 meeting at right angles with the pair of longitudinal members 30 are formed thinner than the longitudinal members 30 as are the pair of transverse members 24 of the base frame 16. Thus, the transverse members 24 of the base frame 16 and of the top frames 17 are thinly formed because the engaging elements (inner pieces 25 and outer pieces 26) of the base frame 16 and of the top frame 17 as well as the support elements (arm support portions 29 and hinge support portions 35) of the pair of arms 18, are provided in a concentrated manner on the longitudinal members 23 and 30 of the base frame 16 and of the top frame 17. Therefore, though the longitudinal members 23 and 30 of the base frame 16 and of the top frame 17 are lengthened, the transverse members 24 and 31 of the base frame 16 and of the top frame 17 can be shortened. It is, therefore, possible to arrange many IC sockets 1 and attachments 15 on the side of the short transverse members 24, 31 on the testing circuit board and, hence, to increase the number that can be mounted.

The pair of arms 18 are obtained through press-punching of a metal plate and folding, and each is constituted by a U-shaped plate 36 of a half-split structure, a pair of coupling portions 37 extending rearward at the ends of the plate 36 on the side opposite to the split surface, and hinge portions 38 provided on the opposing surfaces of the pair of coupling portions 37 of the plate 36. An opening region 41 formed by closing the pair of plates 36 with their split surfaces facing each other is an exposure region for the heat sinks 19 that are in contact with the surface of the BGA chip 10. The exposure region affects the heat radiation of the BGA chip 10. According to the present invention, the IC socket 1 and the attachment 15 are of a split structure making it possible to increase the size of the exposure region for the heat sinks 19 and to enhance the heat radiation.

The heat sinks 19 of a half-split structure are placed on the surfaces of the plates 36 receiving downward urging forces of the coil springs 20. Therefore, when an upward force acts to the back surfaces of the heat sinks 19, the heat sinks 19 move upward against the spring forces. The heat sinks 19 of the half-split structure are held on the plates 36, by the holding members 21 that will be described later, via pairs of coil springs 20, and are allowed to swing in a direction at right angles to the direction of pivot shafts (rotary shafts) of the arms 18. Therefore, when the BGA chip 10 has a surface of varying height, a posture can be accomplished to meet the surface state of the BGA chip 10, and a favorable contact can be maintained. As described above, the heat sinks 19 are allowed to vary in position and posture on the plates 36 against the forces of the coil springs 20, and the back surfaces of the heat sinks 19 can be brought into contact with the surface of the BGA chip 10 in a favorable contacting state.

The coupling portions 37 and the base portions (end portions) of the hinge portions 38 are supported at different portions. The base portions of the coupling portions 37 are pivotally supported by pins 39 at the arm support portions 29 of longitudinal members 23 of the base frame 16, and the base portions of the hinge portions 38 are pivotally supported by pins 40 at the hinge support portions 35 of the top frame 17. Therefore, when the top frame 17 moves downward upon receiving the pushing force, the base portions of the hinge portions 38 move down simultaneously with the top frame 17, whereby the arms 18 turn outward with the base portions of the coupling portions 37 of which the positions do not change, in the up-and-down direction, as fulcrums and the openings of the top frame 17 and of the base frame 16 are opened. When the arms 18 are turned outward, no projection, such as a pin, is present on the upper surfaces 30a of longitudinal members 30 of the top frame 17, and there is no possibility of interference. Conversely, when the pushing force is released and the top frame 17 moves upward, the base portions of hinge portions 38 move up simultaneously with the top frame 17, whereby the arms 18 turn inward with the base portions of the coupling portions 37 of which the positions do not change, in the up-and-down direction, as fulcrums and the openings of the top frame 17 and of the base frame 16 are closed.

The opposing gaps of the pairs of coupling portions 37 and of the pairs of coupling portions 38 provided in an opposing manner on the arms 18, are narrower than the width of the U-shaped plates 36. Therefore, the pairs of coupling portions 37 and the pairs of hinge portions 38 do not expand to the outer sides beyond the U-shaped plates 36, suppressing the size of the attachment 15. It is therefore possible to arrange many IC sockets 1 on the board of the testing circuit on the side of the attachment 15 of a small size, and the BGA chip 10 can be efficiently tested.

The heat sinks 19 are made of a highly heat-conducting aluminum alloy or a copper alloy, each being constituted by a base portion 43 that comes into contact with the surface of the BGA chip 10, and by many heat-radiating fins 44 rising vertically from the base portion 43. The back surface of the base portion 43 comes into contact with the BGA chip 10. Cut-away portions 43a are formed in the base portion 43 at positions corresponding to the leg portions 45 of the holder member 21. Therefore, the holder portion 21 does not interfere with the heat sink 19, and is fixed to the surface of the plate 36 on the arm 18. The heat-radiating fins 44 are erected vertically to the base portion 43. The gaps are arbitrary among neighboring heat-radiating fins 44. At a position where the holder member 21 is fixed, however, the gap between the heat-radiating fins 44 is slightly wider than the gaps at other portions.

The heat sinks 19 of the half-split structure are resiliently provided on the pair of arms 18 on the side of free ends thereof, come in contact with the surface of the BGA chip 10 when the arms 18 are in the closed state, and separate away from the surface of the BGA chip 10 when the arms 18 are in the opened state. When the arms 18 are in the closed state, therefore, the heat generated by the BGA chip 10 can be removed to the exterior. When the arms 18 are in the opened state, the BGA chip 10 can be exchanged.

The holder member 21 is in the shape of a gate, includes a pair of leg portions 45 and a bridge portion 46, and is provided on each plate 36. Threaded holes are formed in the leg portions 45 so as to be communicated with the through holes 36a formed in the plate 36, and the leg portions 45 are fixed to the plate 36 by using screws so that compression coil springs 20 are held compressed between the back surface of the bridge portion 46 and the surface of the base portion 43 of the heat sink 19. Therefore, the heat sinks 19 are urged downward and are prevented from deviating out of the arms 18.

The attachment 15 for a socket is set to the IC socket and is held in the opening in the base frame 16 of the attachment 15. In a state where the IC socket 1 is held, the side walls of the top cover 3 of the IC socket 1 are arranged between the heat sinks 19 and the transverse members 31 of the top frame 17. The upper surface of the top cover 3 of the IC socket 1 is positioned lower than the upper surface of the longitudinal members 30 of the top frame 17.

To mount the BGA chip 10, which is an IC device, on the IC socket, the IC socket 1 and the attachment 15 must be pushed down independently from each other. First, a pushing force is exerted on the upper surface of the top frame 17 of the attachment 15, and the top frame 17 is pushed down in a horizontal state maintaining good balance. In this case, there can be used a rod-like jig in parallel with the transverse members 31. The rod-like jig is arranged nearly in parallel with the pair of transverse members 31 across the pair of longitudinal members 30 of the top frame 17; i.e., the jig comes in contact with the longitudinal members 30 to exert a pushing force on the upper surface of the top frame 17.

When the top frame 17 moves down until the upper surface of the top frame 17 becomes flush with the upper surface of the top cover 3, the jig also comes in contact with the upper surface of the top cover 3 to give a pushing force thereto, and the top cover 3 moves down. Thus, upon separately pushing the attachment 15 and the IC socket 1 by using the jig, a large force does not act in a concentrated manner on only the transverse members 31 of the attachment 15 and, hence, the transverse members 31 can be thin.

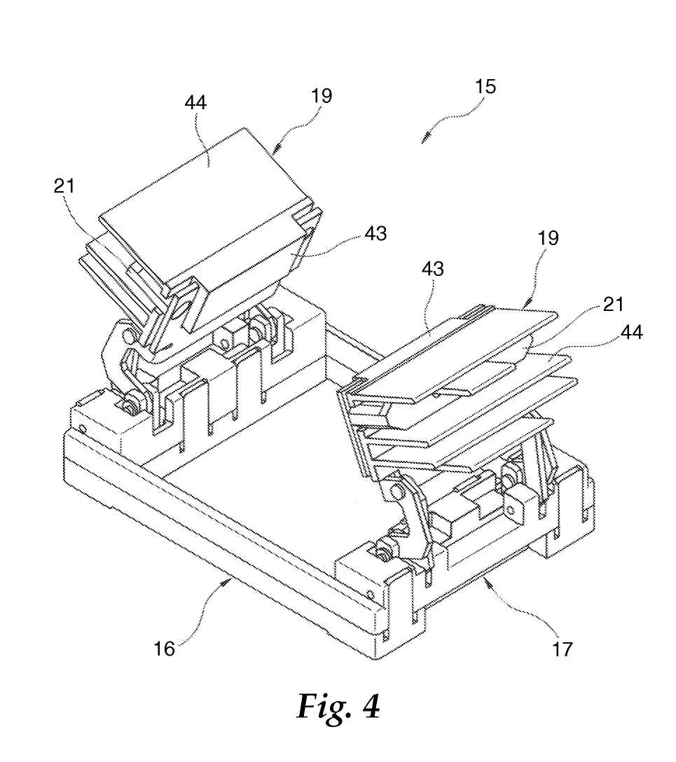

When the top frame 17 moves down, the heat sinks 19 of the half-split structure open outward as shown in FIG. 4. The opening of the top frame 17 is completely opened in a state where the top frame 17 and the top cover 3 are lowest. In this state, the BGA chip 10 is set to the IC socket 1.

Upon contriving the shape and structure of the jig used in this embodiment, the timing for making an electric contact of the BGA chip 10 and a timing for bringing the heat sinks 19 into contact with the surface of the BGA chip 10 can be arbitrarily adjusted. For example, when the BGA chip 10 of a relatively large size is warped or when the BGA chip 10 is not properly arranged in the IC socket 1, the heat sinks 19 are pushed by the jig to mount the BGA chip 10 on a suitable position of the IC socket 1 to make an electric contact. Conversely, the timing may be changed, the BGA chip 10 may be mounted on the IC socket 1 without exerting the pushing force onto the BGA chip 10 via the heat sinks 19 and, thereafter, the heat sinks 19 may be brought in contact with the BGA chip 10.

When the pushing force are released next, the top frame 17 and the top cover 3 move upward, the heat sinks 19 of the half-split structure are closed, and the solder balls of the BGA chip 10 are held by pairs of contact pieces of the contacts to accomplish the electric connection. When the top cover 3 rises to the highest position and the top frame 17 rises up to its highest position, the heat sinks 19 are completely closed, and the lower surfaces of the heat sinks 19 are brought into physical contact with the surface of the BGA chip 10. Thus, the BGA chip 10 is tested to exclude initial defects. In the semiconductor device-testing unit 50 in which the IC socket 1 is assembled with the attachment 15, the BGA chip 10 can be exchanged by applying a force in one axial direction (downwards in the vertical direction). Therefore, conventionally used machines can be modified so as to be automatically operated, making it possible to lower the facility cost.

According to the attachment 15 for a socket according to the embodiment as described above, the IC socket 1 and the heat sinks 19 are of separate and independent structures, and the IC socket 1 is prevented from becoming bulky as a result of a complex structure of the IC socket 1 itself. Further, when either the IC socket 1 or the heat sinks 19 can no longer be used, they can be replaced by new ones offering advantages from the standpoint of reuse, practicability and economy. The heat sinks 19 are not formed in a compact size, and can maintain relatively large contact areas to the BGA chip 10 and can enhance a heat-radiating performance. Further, the pair of heat sinks 19 are of the half-split structure and can be opened and closed, and can be adapted to automatic testing of the BGA chips 10 for their performance, making it possible to efficiently conduct electric performance testing to exclude initial defects.

The present invention is not limited to the above embodiment only but can also be put into practice in other forms. For example, there is no a limitation on the form of the IC socket 1 to which the attachment 5 of the invention is applied, and the attachment 15 can be used with various kinds of IC sockets without heat sink. Further, the shape and size of the heat sinks 19 and the number of the heat-radiating fins can be arbitrarily selected.

1. An attachment, for a socket and used together with a socket for connecting a semiconductor device to a testing circuit to allow testing of said semiconductor devices for performance, comprising:
a pair of heat-radiating portions, of a half-split structure, that can be opened and closed and that are in contact with the surface of said semiconductor device to remove the heat generated by said semiconductor device to the exterior.

2. An attachment, for a socket, according to claim 1, comprising:
a base frame;
a top frame supported on said base frame and resiliently floating thereon; and
a pair of arms of which the ends on one side are fixed ends pivotally coupled to a pair of opposing sides of said top frame, and of which the ends on the other side are free ends, the pair of arms pivotally moving so as to be opened and closed relative to each other while being linked to the lifting motion of said top frame with the pivot shafts as fulcrums;
wherein said pair of heat-radiating portions are resiliently provided on the other end side of said pair of arms, come in contact with the surface of said semiconductor device when said pair of arms are closed, and separate away from the surface of said semiconductor device when said pair of arms are opened.

3. An attachment, for a socket, according to claim 2,
wherein each of the arms comprises a pair of coupling portions supported by said pivot shafts, facing each other on one end side of the arm, and an opposing gap between said pair of coupling portions is equal to, or narrower than, the width of the heat-radiating portions.

4. An attachment, for a socket, according to claim 1,
wherein said heat-radiating portions are provided so as to swing in a direction at right angles to the direction of the pivot shafts of said arms.

5. An attachment, for a socket, according to claim 2,
wherein said base frame is provided with upwardly directed guide pieces which do not protrude beyond the upper surface of said top frame when said top frame is pushed down, said guide pieces being slide-engaged with guide grooves of said top frame to guide the motion of said top frame in the up-and-down direction.

6. An attachment, for a socket, according to claim 1, which is detachably mounted on a circuit board which forms said testing circuit.

7. A semiconductor device-testing unit for connecting a semiconductor device to a testing circuit, to test said semiconductor devices for performance, comprising:
a socket having many contacts which are brought, at the ends on one side thereof, into electric contact with conducting portions exposed on the back surface of said semiconductor device and are brought at the ends on the other side into electric contact with said testing circuit to thereby trunk-connect said semiconductor device to said testing circuit in a state where said semiconductor device is being held; and
the attachment for a socket, of claim 1, that is used together with said socket.
